(19) United States
(12) Patent Application Publication
(10) Pub. No.: US 2015/0097290 A1
(43) Pub. Date: Apr. 9, 2015

(54) COMPOSITE METAL TRANSMISSION LINE BRIDGE STRUCTURE FOR MONOLITHIC MICROWAVE INTEGRATED CIRCUITS (MMICs)

(71) Applicant: Raytheon Company, Waltham, MA (US)

(72) Inventors: Barry J. Liles, Westborough, MA (US); Kamal Tabatabale, Sharon, MA (US); Frederick A. Rose, Atkinson, NH (US); Christopher J. MacDonald, Medford, MA (US); Paul M. Ryan, Boston, MA (US); Kurt V. Smith, Tyngsboro, MA (US); Irl W. Smith, Concord, MA (US)

(73) Assignee: Raytheon Company, Waltham, MA (US)

(21) Appl. No.: 14/045,974

(22) Filed: Oct. 4, 2013

(51) Int. Cl. H01L 23/532

(52) U.S. Cl. CPC H01L 23/53238
USPC 257/751

(57) ABSTRACT

A structure having first and second electrical conductors disposed on a surface of the structure and a bridging conductor connected between the first electrical conductor and the second electrical conductor with portions disposed over the surface of the structure. The bridging conductor includes a plurality of stacked, multi-metal layers, each one of the multi-metal layers having: an electrically conductive layer; and a pair of barrier metal layers, the electrically conductive layer being disposed between and in direct contact with the pair of barrier metal layers.

### TECHNICAL FIELD

This disclosure relates generally to semiconductor structures and manufacturing methods and more particularly to bridge structures for monolithic microwave integrated circuit (MMIC) fabrication.

### BACKGROUND AND SUMMARY

As is known in the art, it is frequently desirable to fabricate, and electrically interconnect, both passive and active microwave components on a common substrate. Such arrangement is commonly referred to as a monolithic microwave integrated circuit. Typically the components are electrically interconnected with microstrip or coplanar waveguide transmission lines. The microstrip transmission line include strip conductor disposed on one surface of the structure and separated from a ground plane conductor under the strip conductor and separated from the strip conductor by a substrate. The coplanar waveguide transmission line also include a strip conductor; however the ground plane conductor is placed in the same plane as the as the strip conductor. More particularly, the strip conductor is disposed on a surface on a substrate between a pair of adjacent ground plane conductors also disposed on the same surface of the substrate. The active devices are typically, for example, heterojunction bipolar transistors (HBTs), field effect transistors (FETs), bipolar devices or PIN diodes. A common substrate material used is silicon carbide with gallium nitride and aluminum gallium nitride epitaxial layers grown on it. Such substrate material is suitable for the transmission line circuitry, the support of passive devices, such as capacitors, and also for formation of single crystal epitaxial layers used to form the active semiconductor region for the HBTs and the FETs.

As is also known in the art, air-bridges are used in these MMICs. For example, many active devices are formed with inter-digitated electrodes. For example, FETs (or bipolar transistors) adapted to operate at high frequencies are sometimes formed with finger shaped gate electrodes (or base electrodes) and finger shaped drain electrodes (or collector electrodes). The finger shaped electrodes are disposed in an inter-digitated relationship over a surface of a semiconductor body. Source electrodes (or emitter electrodes) are disposed over the surface and are positioned between a pair of the gate electrodes (or base electrodes). The gate electrodes (or base electrodes) are electrically connected, at proximal ends thereof, to a bus disposed on the surface of the semiconductor. Likewise, the drain electrodes (or collector electrodes) are electrically connected, at proximal ends thereof, to a bus disposed on the surface of the semiconductor body. The source electrodes are typically connected using air bridging conductors, sometimes referred to as air-bridges, which have ends connected to a pair of the source electrodes and which are elevated over (suspended in air) the surface of the substrate to thereby span over gate and drain electrodes. The latter technique is described in U.S. Pat. No. 4,456,888, issued Jun. 26, 1984 and entitled “Radio Frequency Network Having Plural Electrically Interconnected Field Effect Transistor Cells”.

One metal structure used to form theses air-bridges uses evaporated gold as described in U.S. Pat. No. 5,646,450, inventors Liles et al, issued Jul. 8, 1997, and assigned to the same assignee as the present invention.

In the case of coplanar waveguide, a metal conductor is used to connect the pair of ground plane conductors on either side of the strip conductor, and a portion of the strip conductor is formed as an air-bridge structure over the metal conductor. As noted above, coplanar waveguide transmission lines include a strip conductor and the pair of ground plane conductors is on either side of the strip conductor. Thus, the strip conductor is between a pair of adjacent, coplanar, ground plane conductors. In many applications it is necessary to connect the pair of adjacent ground plane conductors. For this purpose, as noted above, a metal conductor is used to connect the pair of ground plane conductors on either side of the strip conductor, and a portion of the strip conductor is formed as an air-bridge structure over the metal conductor. These strip conductor air-bridges formed with existing technology have proven inadequate in many current, very high-power gallium-nitride MMICs.

In accordance with the present disclosure, a structure is provided having: a first electrical conductor disposed on a surface of the structure; a second electrical conductor disposed on the surface of the structure; and a bridging conductor connected between the first electrical conductor and the second electrical conductor and having portions over the surface of the structure. The bridging conductor includes: an electrically conductive layer; a barrier metal layer on the conductive metal layer; and a refractory metal layer on the barrier metal layer.

In one embodiment, the bridging conductor includes: a second refractory metal layer to provide a pair of refractory metal layers; and a second bather metal layer to provide a pair of barrier metal layers. Each one of the barrier metal layers is on an opposite one of a pair of surfaces of the metal layer. The pair of refractory metal layers is on a corresponding one of the pair of barrier metal layers.

In one embodiment, the bridging conductor includes: a second barrier layer to provide a pair of barrier layers; and each one of the barrier metal layers is on an opposite one of a pair of surfaces of the metal layer.

In one embodiment, the electrically conductive layer is gold.

In one embodiment, the bather layer is platinum.

In one embodiment, the barrier layer is platinum, or an inter-metallic compound of: platinum and titanium, or palladium and cobalt, or titanium nitride.

In one embodiment, the barrier layer is a diffusion barrier layer disposed to prevent the refractory metal in the refractory metal layer from diffusing into the electrically conductive layer.

In one embodiment, a structure is provided having: a first electrical conductor disposed on a surface of the structure; a second electrical conductor disposed on the surface of the structure; and a bridging conductor connected between the first electrical conductor and the second electrical conductor and having portions disposed over the surface of the semiconductor structure. The bridging conductor comprising a plurality of stacked, multi-metal layers, each one of the multi-metal layers, comprising: a refractory metal layer; an electrically conductive layer; and a barrier metal layer. The barrier metal layer is disposed on the electrically conductive layer. The refractory metal layer is disposed on the barrier metal layer.

In one embodiment, the bridging conductor includes a plurality of stacked, multi-metal layers, each one of the multi-metal layers having: an electrically conductive layer; and a pair of barrier metal layers, the electrically conductive layer being disposed between and in direct contact with the pair of barrier metal layers. A pair of refractory metal layers is included and the pair of refractory metal layers is disposed between the pair of barrier metal layers.

In one embodiment, the electrically conductive layer is disposed between and in direct contact with the pair of barrier metal layers.

The inventors have recognized that while the air-bridge structure as described in U.S. Pat. No. 5,646,450 performs well under many conditions, the inventors of the subject patent application have recognized that restructuring and cracking of evaporated gold air-bridges occurs during pulsed operation of MMICs at high RF power levels. More particularly, the inventors of the subject patent application have discovered that structure in U.S. Pat. No. 5,646,450 comprised alternating layers of gold and a refractory metal to limit the size to which gold grains could grow. While the structure in U.S. Pat. No. 5,646,450 (which used titanium as the preferred refractory metal) had good performance at intermediate RF power levels, it is marginal at the RF power levels experienced, for example, in current large-periphery gallium nitride MMICs. The inventors of the subject patent application have discovered that current MMICs show restructuring of their air-bridges after several hundred hours, that some of the air-bridges eventually fail at these high RF power levels, that these failures are due to inter-diffusion of titanium and gold at high RF currents, and that the metal stack must be modified to prevent this potential failure.

More particularly, the inventors of the present patent application have discovered that a problem with the structure described in U.S. Pat. No. 5,646,450 was that if the temperature of part of an air-bridge reached 200° C., the titanium interlayer would diffuse into the gold increasing the metal resistance and destroying the layered structure allowing restructuring of the gold during pulsed operation. The result was distortion, and eventual failure of the air-bridge. The solution was to add a diffusion barrier layer to both sides of the titanium layers to prevent the titanium layers from diffusing into the gold on either side. The diffusion barrier layers may be, for example, a thin layer of platinum (which can be between 10 and 1000 Angstroms thick), or a platinum layer or an inter-metallic compound of platinum and titanium. Other metals can be substituted for platinum and titanium (e. g., palladium and cobalt). Further, the composite may be a single, heat-resistant metal (e. g., platinum could be used.) A layered structure may be used to stabilize thicker layers of other metals (e.g., copper which behaves similarly to gold could be used in this layered structure in place of gold).

Thus, several metals (for example Pt—Ti—Pt) in place of a single layer of Ti are used to extend the temperature range in which the complete stack, including the thick layers of gold, resists restructuring and thereby allows air-bridges in RF lines to be stable at substantially higher RF power levels with pulsed operation.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is an isometric view, somewhat out of proportion and simplified, of a semiconductor structure having an air bridge structure according to the disclosure;

FIG. 2 is a cross-sectional view of an air-bridge structure according to the disclosure, here such air-bridge structure being used in the semiconductor structure of FIG. 1 taken along lines 3-3 in FIG. 1;

FIG. 3 is an enlarged cross-sectional view of the semiconductor structure of FIG. 2 taken along lines 3-3; and

FIG. 4 is a perspective view of a portion of a coplanar waveguide having the air-bridge structure of FIG. 1 according to the disclosure;

FIG. 5 is a cross section of a multi-metal stack used for an air-bridge structure of FIG. 4 according to the disclosure; and

FIG. 6 is a cross section of multi-metal stack used for an air-bridge structure used for an air-bridge structure of FIG. 4 according to an alternative embodiment of the disclosure.

Like reference symbols in the various drawings indicate like elements.

### DETAILED DESCRIPTION

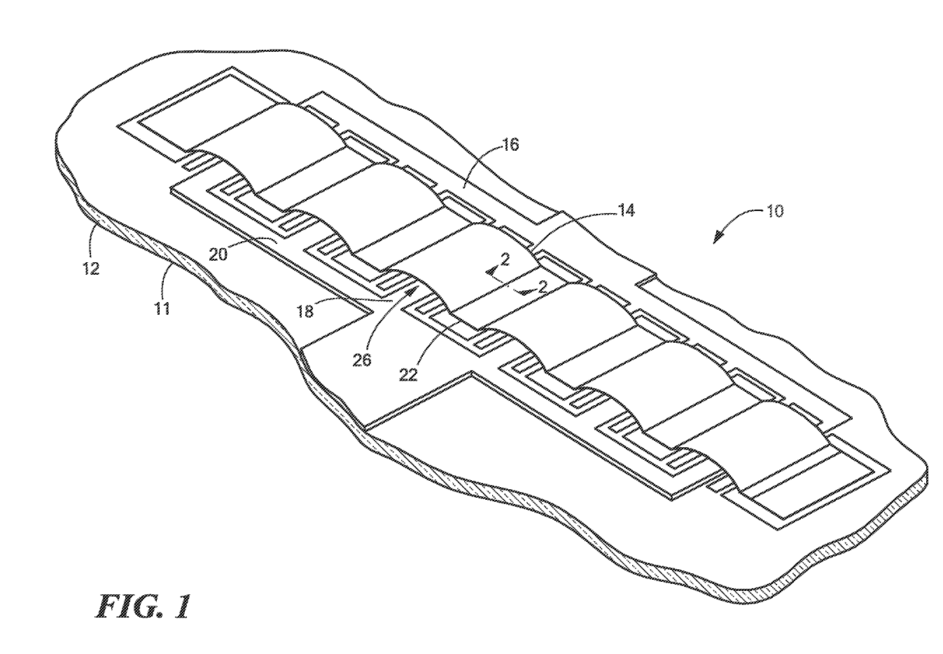

Referring now to FIG. 1, a semiconductor structure 10 is shown, here a Metal-Semiconductor Field Effect Transistor (MESFET) which is part of a monolithic microwave integrated circuit (MMIC). The structure 10 includes a semiconductor substrate 12, here of, for example, SiC, having a column III-V epitaxial layer, for example a GaN epitaxial layer with an AlGaN epitaxial layer on the GaN all disposed on the upper surface and a ground plane conductor 11 formed on the bottom surface of the substrate 12, here, for example, configured as microstrip transmission line, as shown. The structure 10 includes a plurality of gate electrodes as typified by gate electrode 14 which is connected to a common bus 16 as shown. The structure 10 still further includes a plurality of source electrodes as typified by source electrode 22. The plurality of source electrodes as typified by source electrode 22 are connected by bridging conductor 24 which is separated from the gate electrodes as typified by gate electrode 14 and the drain electrodes as typified by drain electrode 18 with an air gap 26. Thus, the bridging conductor 24 is connected between the source electrodes 22 disposed on the surface of the substrate 12 and has portions disposed over the surface of the substrate 12.

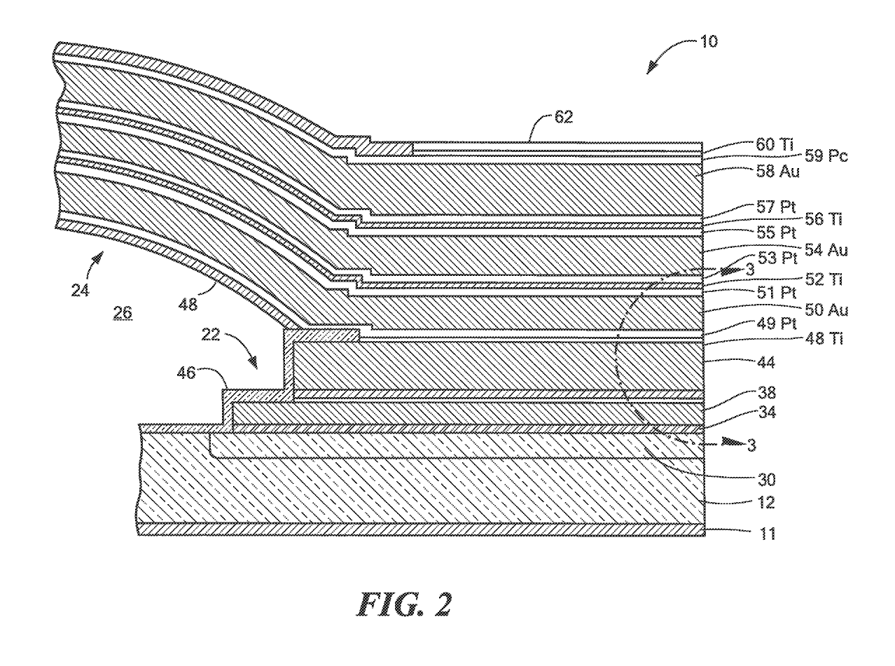

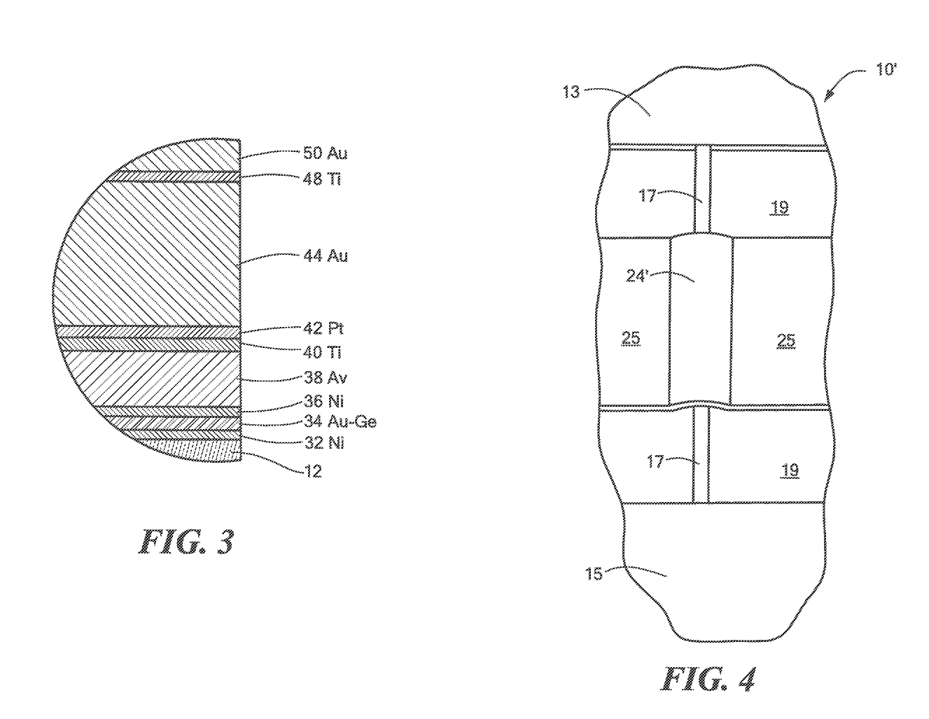

Referring now to FIGS. 2 and 3, a portion of the structure 10 is shown to include the substrate 12 and the ground plane conductor 11 formed on the bottom surface of the substrate 12. Typically, the substrate 12 has a thickness of 500 microns for coplanar waveguide circuits. To provide the structure 10, a plurality of mesas is formed in the epitaxial layer 30 are formed on the top surface of the substrate 12 in accordance with techniques well known in the art. Here, for example, the epitaxial layer 30 is a 2 micron thick gallium-nitride (GaN) epitaxial layer 30 followed by a 25 nanometer AlGaN layer grown on the substrate 12. The active regions of, in this example, GaN HEMTs are formed by etching isolated mesas in the epitaxial layer 30.

It should be appreciated that sequentially vapor-phase epitaxial deposited techniques could also be used as well as other layer forming techniques. First a layer 32 of nickel having a thickness of 50 angstroms is deposited followed by a layer 34 of a gold-germanium alloy having a thickness of 900 angstroms. Next a layer 36 of nickel having a thickness of 300 angstroms is deposited followed by a layer 38 of gold having a thickness of 3000 angstroms. Next a layer 40 of titanium having a thickness of 1000 angstroms is deposited followed by a layer 42 of platinum having a thickness of 1000 angstroms. Finally, completing the source electrode 22, a layer 44 of gold having a thickness of 8000 angstroms is deposited. It should be appreciated that the drain electrodes are fabricated in a like manner during the just described process using known techniques.

Having formed the electrodes, a layer 46 of silicon nitride (Si₃N₄) having a thickness of 2000 angstroms is deposited to provide passivation and a capacitance dielectric and to raise the transmission line from the epitaxial material. Next, a mask is laid over the structure 10 and portions of the layer 46 are etched away as required such that the surfaces beneath the layer 46 are exposed.

It should be appreciated that a layer of photoresist or like material is deposited under the bridging conductor 24 before a layer 48 is deposited to form the shape of the bridging conductor 24 and after the bridging conductor 24 is formed the layer of photoresist is etched away to provide the air gap 26.

The bridging conductor 24 is fabricated from a stack of multi-metal layers to reduce the restructuring of the bridging conductors. In embodiment shown, to form the bridging conductor 24, typical of the plurality of bridging conductors, a layer 48 of titanium having a thickness of 500 angstroms is deposited followed by a diffusion barrier layer 49 of platinum having a thickness of 250 angstroms, followed by a layer 50 of a conductive metal, here gold, having a thickness of 9000 angstroms (except for the last upper most layer where the thickeners is 12000 angstroms) followed by another layer 51 of platinum having a thickness of 250 angstroms. Thus, each of the multi-metal layers includes: a refractory metal layer; a diffusion barrier layer on the refractor metal layer; a conductive layer having a bottom surface on, and in direct contact, with the diffusion barrier layer; and a second diffusion barrier layer, on and in direct contact with, the upper surface of the conductive layer. Here, three such multi-metal layers in the stack. Disposed on the upper surface of the stack is another refractory metal layer.

Thus, a layer 52 of titanium having a thickness of 500 angstroms is deposited followed by a layer 53 of platinum having a thickness of 250 angstroms, followed by a layer 54 of gold having a thickness of 9000 angstroms. Next a layer 55 of platinum having a thickness of 250 angstroms is deposited followed by a layer 56 of titanium having a thickness of 500 angstroms is deposited followed by a layer 57 of platinum having a thickness of 250 angstroms followed by a layer 58 of gold having a thickness of 12000 angstroms. Next a layer 59 of platinum having a thickness of 250 angstroms is deposited followed by a layer 60 of titanium having a thickness of 500 angstroms is deposited. A glassivation layer 62 of, for example, silicon nitride (Si₃N₄) having a thickness of 1000 angstroms is deposited over the layer 60 of titanium and a mask (not shown) is laid over the structure 10 and portions of the layer 60 and the layer 62 are etched away such that the surfaces beneath the layer 60 are exposed to provide for wire bonding to the gold as required.

It should be appreciated that the number of alternating layers of titanium-platinum-gold-platinum may be changed as well as the thickness of each of the layers. In some applications, partial restructuring of the top layer may be permitted eliminating the need for the glassivation layer 62. For example, other refractory metals may be used. Further, the barrier layers may be platinum, or an inter-metallic compound of: platinum and titanium, or palladium and cobalt, for example, to prevent the refractory metal in the refractory metal layers from diffusing into the gold electrically conductive layer.

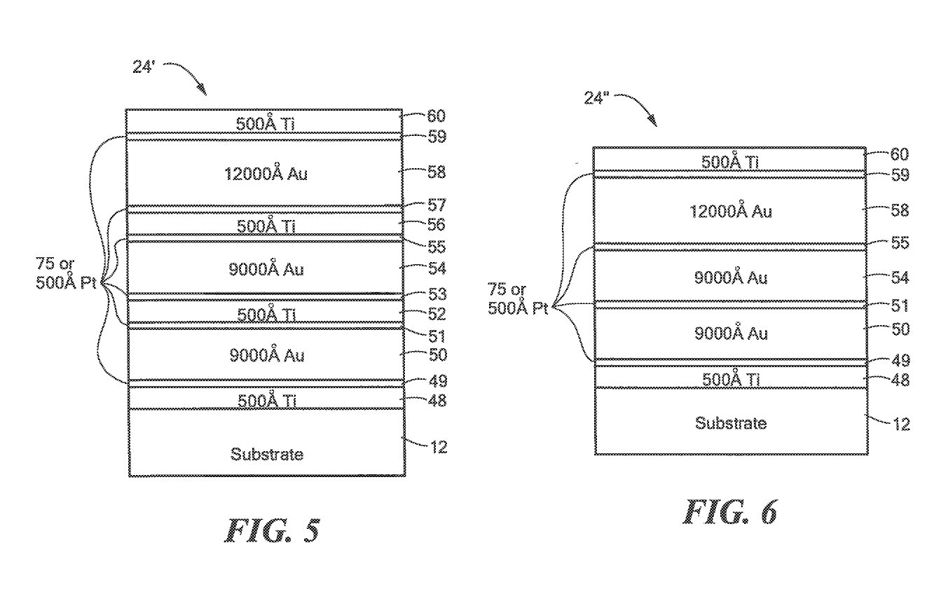

Referring now to FIG. 4, a coplanar waveguide CPW structure 10′ is shown having a strip conductor 25 disposed between a pair of coplanar ground plane conductors 13, 15 on here, for example, a 500 micron thick silicon-carbide substrate 19. An electrical conductor 17 is used to electrically interconnect the pair of ground plane conductors 13, 15. A portion of the strip conductor is formed as an air-bridge conductor 24′, as shown, so that it is suspended over the electrical conductor 17, as shown. A cross section of the air-bridge structure 24′ is shown in FIG. 5 to include a substrate 12 having the multi-metal layers shown in FIG. 2. Thus, the air-bridge conductor 14′ includes, as shown in FIG. 5, a layer 48 of titanium having a thickness of 500 angstroms, a diffusion barrier layer 49 of platinum having a thickness of 75, 150 or 250 angstroms, for example, on the layer 48; a layer 50 of a conductive metal, here gold, having a thickness of 9000 angstroms on the layer 49; a layer 51 of platinum having a thickness of 75, 150 or 250 angstroms, for example, on the layer 50; a layer 52 of titanium having a thickness of 500 angstroms on layer 51; a layer 53 of platinum having a thickness of 75, 150 or 250 angstroms, for example, on layer 52; a layer 54 of gold having a thickness of 9000 angstroms on layer 53; a layer 55 of platinum having a thickness of 75, 150, or 250 angstroms, for example, on layer 54; a layer 56 of titanium having a thickness of 500 angstroms on layer 55; a layer 57 of platinum having a thickness of 75, 150 or 250 angstroms on layer 56; a layer 58 of gold having a thickness of 12000 angstroms on layer 57; a layer 59 of platinum having a thickness of 75, 150 or 250 angstroms, for example, on layer 58; and a layer 60 of titanium having a thickness of 500 angstroms on layer 59.

It should be noted that under the air bridges in the transmission lines the AlGaN layer is etched away although GaN is still present. This is part of the process of isolating the active (conducting) regions of the HEMT. The AlGaN is present only under the air bridges on the HEMT itself.

Referring to FIG. 6, an alternative multi-metal stack is shown for an air-bridge structure 24″ a semiconductor structure or for a CPW, for example, according to the disclosure is shown. Here, the multi-metal stack removes the titanium layer 52, the platinum layer 53, the titanium layer 56, and the platinum layer 57. Thus, the stack includes: a layer 48 of titanium having a thickness of 500 angstroms, a diffusion barrier layer 49 of platinum having a thickness of 75, or 250 angstroms, for example, on the layer 48; a layer 50 of a conductive metal, here gold, having a thickness of 9000 angstroms on the layer 49; a layer 51 of platinum having a thickness of 75 or 250 angstroms, for example, on the layer 50; a layer 54 of gold having a thickness of 9000 angstroms on layer 51; a layer 55 of platinum having a thickness of 75 or 250 angstroms, for example, on layer 54; a layer 58 of gold having a thickness of 12000 angstroms on layer 55; a layer 59 of platinum having a thickness of 75 or 250 angstroms, for example, on layer 58; and a layer 60 of titanium having a thickness of 500 angstroms on layer 59.

It is noted that in both stacks, there is a diffusion barrier layer, for example platinum, on both surfaces of the gold layer and further that there is a diffusion barrier layer of, for example, platinum, between the refractory metal layer, for example titanium, and the gold layer.

A number of embodiments of the disclosure have been described. Nevertheless, it will be understood that various modifications may be made without departing from the spirit and scope of the disclosure. For example, while the multi-metal layer structure has been described in connection with air-bridges it may be used in other bridges as where there is a solid dielectric under the bridge. Further, other barrier metal layers may be used such as, for example, or an inter-metallic compound of: platinum and titanium, or palladium and cobalt, or titanium nitride. Accordingly, other embodiments are within the scope of the following claims.

What is claimed is:

1. A structure, comprising:
a first electrical conductor disposed on a surface of the structure;
a second electrical conductor disposed on the surface of the structure;
a bridging conductor connected between the first electrical conductor and the second electrical conductor and having portions over the surface of the structure, the bridging conductor comprising:
an electrically conductive layer;
a barrier metal layer on the conductive metal layer; and
a refractory metal layer on the barrier metal layer.

2. The structure recited in claim 1 wherein the bridging conductor includes:
a second refractory metal layer to provide a pair of refractory metal layers; and
a second barrier metal layer to provide a pair of barrier metal layers; and
wherein each one of the barrier metal layers is on an opposite one of a pair of surfaces of the metal layer, and wherein
the pair of refractory metal layers is on a corresponding one of the pair of barrier metal layers.

3. The structure recited in claim 1 wherein the bridging conductor includes:
a second barrier layer to provide a pair of barrier layers; and
wherein each one of the barrier metal layers is on an opposite one of a pair of surfaces of the metal layer.

4. The structure recited in claim 1 wherein the electrically conductive layer is gold.

5. The structure recited in claim 1 wherein the barrier layer is platinum.

6. The structure recited in claim 1 wherein the barrier layer is platinum, or an inter-metallic compound of platinum and titanium, or palladium and cobalt.

7. The structure recited in claim 1 wherein the barrier layer is a diffusion barrier layer disposed to prevent the refractory metal in the refractory metal layer from diffusing into the electrically conductive layer.

8. The structure recited in claim 3 wherein the barrier layers are diffusion barrier layers disposed to prevent the refractory metal in the refractory metal layer from diffusing into the electrically conductive layer.

9. A structure, comprising:
a first electrical conductor disposed on a surface of the structure;
a second electrical conductor disposed on the surface of the structure;
a bridging conductor connected between the first electrical conductor and the second electrical conductor and having portions disposed over the surface of the semiconductor structure, the bridging conductor comprising a plurality of stacked, multi-metal layers, each one of the multi-metal layers, comprising:
a refractory metal layer;
an electrically conductive layer;
a pair of barrier metal layers;
wherein the electrically conductive layer is disposed between the pair of barrier metal layers; and
wherein the refractory metal layer is disposed on one of the pair of barrier metal layers.

10. The structure recited in claim 9 wherein the electrically conductive layer is gold.

11. The structure recited in claim 10 wherein the barriers layers are platinum.

12. The structure recited in claim 9 wherein the barrier layers are platinum, or an inter-metallic compound of: platinum and titanium, or palladium and cobalt.

13. The structure recited in claim 9 wherein the barrier layers are diffusion barrier layers disposed to prevent the refractory metal in the refractory metal layers from diffusing into the electrically conductive layer.

14. The structure recited in claim 10 wherein the barrier layers are diffusion barrier layers disposed to prevent the refractory metal in the refractory metal layers from diffusing into the electrically conductive layer.

15. A structure, comprising:
a first electrical conductor disposed on a surface of the structure;
a second electrical conductor disposed on the surface of the structure;
a bridging conductor connected between the first electrical conductor and the second electrical conductor and having portions disposed over the surface of the semiconductor structure, the bridging conductor comprising a plurality of stacked, multi-metal layers, each one of the multi-metal layers, comprising:
a refractory metal layer;
an electrically conductive layer;
a barrier metal layer;
wherein the barrier metal layer is disposed on the electrically conductive layer; and
wherein the refractory metal layer is disposed on the pair of barrier metal layer.
